(19) United States
(12) Patent Application Publication
(10) Pub. No.: US 2016/0056142 A1
(43) Pub. Date: Feb. 25, 2016

(54) SEMICONDUCTOR DEVICE

(71) Applicant: Kabushiki Kaisha Toshiba, Tokyo (JP)

(72) Inventor: Masayuki Kaida, Kakogawa Hyogo (JP)

(21) Appl. No.: 14/632,516

(22) Filed: Feb. 26, 2015

(30) Foreign Application Priority Data
Aug. 22, 2014 (JP) 2014-169611

(51) Int. Cl. H01L 27/02; H01L 29/36; H01L 29/06; H01L 23/528

(52) U.S. Cl. CPC H01L 27/0255; H01L 23/528; H01L 29/36; H01L 29/0684

(57) ABSTRACT

According to one embodiment, semiconductor device includes a first semiconductor region; a second semiconductor region; a first insulating layer; a second insulating layer; a third semiconductor region; and an interconnect layer. The second semiconductor region is provided on the first semiconductor region, and second semiconductor region is connected to the first semiconductor region. The first insulating layer surrounds a first portion of the second semiconductor region. The second insulating layer surrounds a second portion of the second semiconductor region. The third semiconductor region is provided on the second portion of the second semiconductor region, the third semiconductor region is connected to the second portion, and the third semiconductor region is surrounded by the second insulating layer. And the interconnect layer is provided on the second semiconductor region and the third semiconductor region, and the interconnect layer is electrically connected to the second semiconductor region and the third semiconductor region.

### CROSS-REFERENCE TO RELATED APPLICATIONS

This application is based upon and claims the benefit of priority from Japanese Patent Application No. 2014-169611, filed on Aug. 22, 2014; the entire contents of which are incorporated herein by reference.

### FIELD

Embodiments described herein relate generally to a semiconductor device.

### BACKGROUND

A semiconductor device used in an electronic equipment, an electronic system or the like includes an ESD (Electro Static Discharge) protection diode that protects an internal circuit against static electricity applied to a signal terminal from the outside. As the frequency of a signal flowing through a transmission line is increased, the capacitance of the ESD protection diode is required to be decreased.

As a method of device isolation of a diode included in the ESD protection diode, there is a method of device isolation of the diode by an impurity diffusion layer. However, in order to form the impurity diffusion layer, it is necessary to perform thermal treatment for a long time. Hence, impurity elements are diffused from a semiconductor substrate to an epitaxial layer, and thus the effective thickness of the epitaxial layer is reduced. In other words, the distance between electrodes of a parasitic capacitance is substantially shortened, and thus it is difficult to reduce the capacitance.

Since the impurity diffusion layer is formed by the diffusion of the impurity elements, the distance between respective diodes is increased according to the diffusion. Thus, the interconnect distance between diodes is increased, and limitation on the reduction is generated in an interconnect capacity.

### BRIEF DESCRIPTION OF THE DRAWINGS

FIG. 1A is a schematic plan view showing a semiconductor device according to a first embodiment, and FIG. 1B is a schematic cross-sectional view taken along line A-A′ of the semiconductor device according to the first embodiment shown in FIG. 1A;

FIGS. 2A and 2B are schematic cross-sectional views showing part of a semiconductor device according to a reference example;

FIG. 3A is a schematic plan view showing a semiconductor device according to a second embodiment, and FIG. 3B is a schematic cross-sectional view taken along line A-A′ of the semiconductor device according to the second embodiment shown in FIG. 3A;

FIG. 4 is a schematic cross-sectional view showing part of a semiconductor device according to a third embodiment;

FIG. 5 is a schematic cross-sectional view showing part of a semiconductor device according to a fourth embodiment;

FIG. 6 is a schematic cross-sectional view showing part of a semiconductor device according to a fifth embodiment; and

FIG. 7 is a schematic cross-sectional view showing part of a semiconductor device according to a sixth embodiment.

### DETAILED DESCRIPTION

In general, according to one embodiment, a semiconductor device includes a first semiconductor region of first conductivity-type; a second semiconductor region of second conductivity-type; a first insulating layer; a second insulating layer; a third semiconductor region of first conductivity-type; and an interconnect layer.

The second semiconductor region of second conductivity-type is provided on the first semiconductor region, and second semiconductor region is connected to the first semiconductor region. The first insulating layer surrounds a first portion of the second semiconductor region. The second insulating layer surrounds a second portion of the second semiconductor region. The third semiconductor region of first conductivity-type is provided on the second portion of the second semiconductor region, the third semiconductor region is connected to the second portion, and the third semiconductor region is surrounded by the second insulating layer. And the interconnect layer is provided on the second semiconductor region and the third semiconductor region, and the interconnect layer is electrically connected to the second semiconductor region and the third semiconductor region.

Embodiments of the invention will now be described with reference to the drawings. In the following description, like components are marked with like reference numerals, and the description of components which are once described will be omitted as appropriate.

### First Embodiment

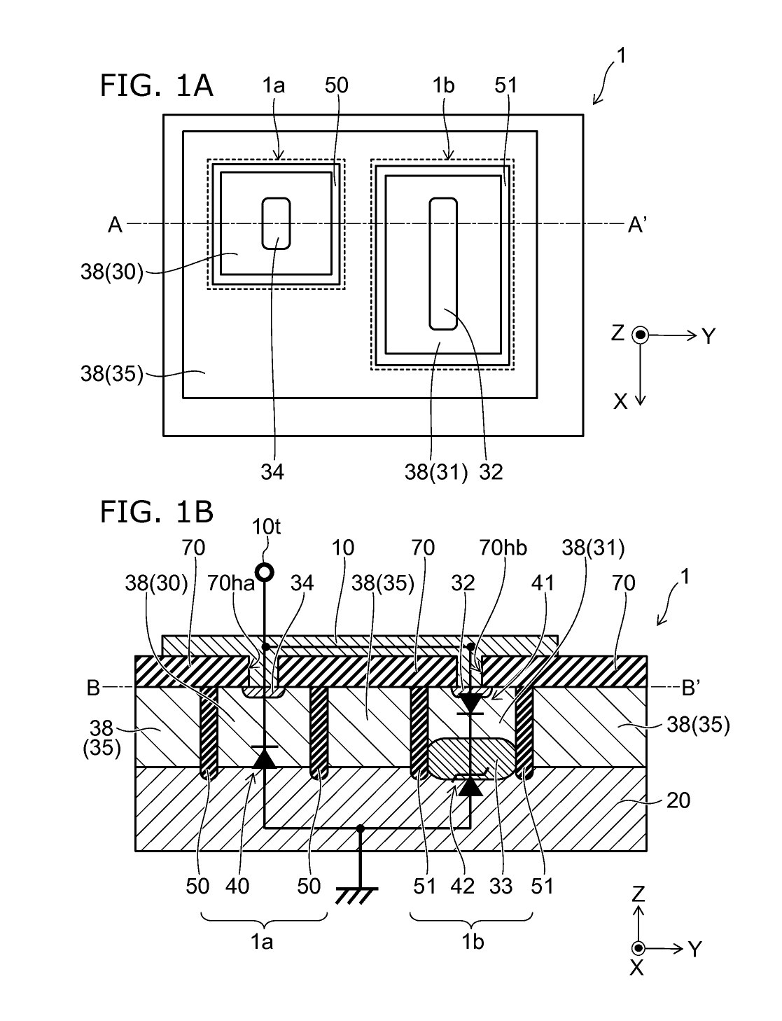

FIG. 1A is a schematic plan view showing a semiconductor device according to a first embodiment, and FIG. 1B is a schematic cross-sectional view taken along line A-A′ of the semiconductor device according to the first embodiment shown in FIG. 1A.

FIG. 1A shows the upper face of a cross section taken along line B-B′ of FIG. 1B.

A semiconductor device 1 according to the first embodiment includes an ESD protection diode.

The semiconductor device 1 includes a p⁺-type first semiconductor region 20 (hereinafter, for example, a semiconductor region 20) that is a semiconductor substrate. The semiconductor region 20 is grounded. An n-type second semiconductor region 38 (hereinafter, for example, a semiconductor region 38), that is connected to the semiconductor region 20, is provided on the semiconductor region 20. The semiconductor region 38 includes a first portion 30 surrounded by a first insulating layer 50 (hereinafter, for example, an insulating layer 50), a second portion 31 surrounded by a second insulating layer (hereinafter, for example, an insulating layer 51) and a third portion 35 other than these portions. For example, the first portion 30 is completely surrounded by the insulating layer 50, and the second portion 31 is completely surrounded by the insulating layer 51 as viewed from Z direction. Here, the first portion 30 is located in a first region 1a of the semiconductor device 1, and the second portion 31 is located in a second region 1b of the semiconductor device 1 apart from the first region 1a. In the semiconductor device 1, a p-n diode 40 is formed by the p⁺-type semiconductor region 20 and the n-type first portion 30. The insulating layer 50 is an element isolation region of the p-n diode 40.

A p-type third semiconductor region 32 (hereinafter, for example, a semiconductor region 32), that is connected to the second portion 31, is provided on the second portion 31 of the semiconductor region 38. In the semiconductor device 1, the p-type semiconductor region 32 and the n-type second portion 31 form a p-n diode 41. The direction of the p-n diode 41 from the p-side to the n-side is opposite to the direction of the p-n diode 40 from the p-side to the n-side. The second portion 31 of the semiconductor region 38 and the semiconductor region 32 are surrounded by a second insulating layer 51 (hereinafter, for example, an insulating layer 51).

An interconnect layer 10 is provided on the semiconductor region 38 and on the semiconductor region 32. The interconnect layer 10 is connected to a terminal 10t of the semiconductor device 1. The interconnect layer 10 is electrically connected to the first portion 30 of the semiconductor region 38 and the semiconductor region 32.

An n⁺-type fourth semiconductor region 33 (hereinafter, for example, a semiconductor region 33) is provided between the semiconductor region 20 and the second portion 31 of the semiconductor region 38. The semiconductor region 33 is a region that is obtained by implanting n-type impurity elements between the semiconductor region 20 and the semiconductor region 38, and then by thermally diffusing the impurity elements. The semiconductor region 33 is connected to the second portion 31 of the semiconductor region 38 and the semiconductor region 20. The impurity concentration in the semiconductor region 33 is higher than that in the semiconductor region 38. The semiconductor region 33 is surrounded by the insulating layer 51. In the semiconductor device 1, the p⁺-type semiconductor region 20 and the n⁺-type semiconductor region 33 form a Zener diode 42. The insulating layer 51 is an element isolation region of the p-n diode 41 and the Zener diode 42.

An n⁺-type sixth semiconductor region 34 (hereinafter, for example, a semiconductor region 34) is provided between the first portion 30 of the semiconductor region 38 and the interconnect layer 10. The semiconductor region 34 is in ohmic contact with the interconnect layer 10. The impurity concentration in the semiconductor region 34 is higher than that in the semiconductor region 38. The third portion 35 of the semiconductor region 38 is provided on the outside of the first portion 30 and on the outside of the second portion 31 of the semiconductor region 38. The semiconductor region 38 is an n-type epitaxial growth layer provided on the semiconductor region 20.

An interlayer insulating film 70 is provided on the semiconductor region 38. The interlayer insulating film 70 includes openings 70ha and 70hb. The interconnect layer 10 is connected through the opening 70ha to the semiconductor region 34, and is connected through the opening 70hb to the semiconductor region 32.

The main ingredient of each semiconductor region is, for example, silicon (Si). The main ingredient of each semiconductor region may be, for example, silicon carbide (SiC) or gallium nitride (GaN). In the embodiment, unless otherwise particularly indicated, the impurity concentration of the n type (second conductivity-type) is decreased in the order of the n⁺ type and the n type. The impurity concentration of the p type (first conductivity-type) is decreased in the order of the p⁺ type and the p type.

As the n⁺-type, n-type and other conductivity-type impurity elements, for example, phosphorus (P), arsenic (As) and the like are applied. As the p⁺-type, p-type and other conductivity-type impurity elements, for example, boron (B) and the like are applied. Even when in the semiconductor device 1, the p-type and n-type conductivity types are exchanged, the same effect is obtained.

The material of the interconnect layer 10 is a metal that includes at least one selected from a group consisting of aluminum (Al), titanium (Ti), nickel (Ni), tungsten (W), gold (Au) and the like. The material of the insulating layer and the interlayer insulating film includes, for example, a silicon oxide, a silicon nitride or the like.

In the semiconductor device 1, as an example, a crowbar-type circuit is formed. For example, the p-n diode 40 and a pair of the p-n diode 41 and the Zener diode 42 are connected parallel to each other.

When a positive transient voltage is applied to the terminal 10t, the p-n diode 41 is biased in the forward direction, the Zener diode 42 is biased in the reverse direction and the p-n diode 40 is biased in the reverse direction.

The breakdown voltage of the Zener diode 42 can be arbitrarily set. Hence, the breakdown voltage of the p-n diode 40 is set lower than the breakdown voltage of the Zener diode 42, and thus a current does not flow through the p-n diode 40 in the reverse direction, and a current flows through the Zener diode 42 in the reverse direction.

Accordingly, a transient current when the positive transient voltage is applied to the terminal 10t flows from the terminal 10t through the p-n diode 41 and the Zener diode 42 to the semiconductor region 20.

On the other hand, when a negative transient voltage is applied to the terminal 10t, the p-n diode 41 is biased in the reverse direction, the Zener diode 42 is biased in the forward direction and the p-n diode 40 is biased in the forward direction. Since the forward voltage of the p-n diode 40 is lower than the breakdown voltage of the p-n diode 41, a transient current flows from the semiconductor region 20 through the p-n diode 40 to the terminal 10t.

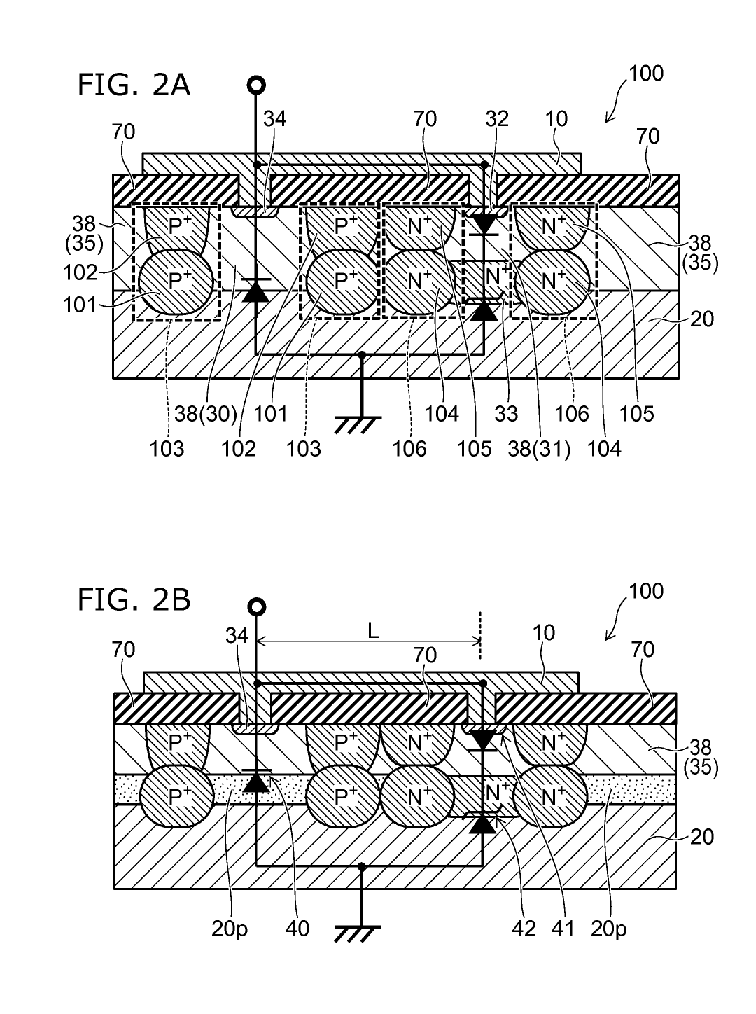

FIGS. 2A and 2B are schematic cross-sectional views showing part of a semiconductor device according to a reference example.

Here, FIG. 2B shows a state after thermal diffusion has progressed as compared with FIG. 2A.

In a semiconductor device 100 according to the reference example, the first portion 30 of the semiconductor region 38 is surrounded by a p⁺-type semiconductor region 101 and a p⁺-type semiconductor region 102. The semiconductor regions 101 and 102 are regions that are obtained by implanting p-type impurity elements into around the first portion 30 of the semiconductor region 38, and then by thermally diffusing the impurity elements. In the reference example, the semiconductor region 101 and the semiconductor region 102 are an element isolation region 103.

In the semiconductor device 100 according to the reference example, the semiconductor regions 31 to 33 are surrounded by an n⁺-type semiconductor region 104 and an n⁺-type semiconductor region 105. The semiconductor regions 104 and 105 are regions that are obtained by implanting n-type impurity elements into around the semiconductor regions 31 to 33, and then by thermally diffusing the impurity elements. In the reference example, the semiconductor region 104 and the semiconductor region 105 are an element isolation region 106. The semiconductor region 38 is an epitaxial growth layer provided on the semiconductor region 20.

However, in the process of manufacturing the semiconductor device 100, a thermal treatment process for forming an element isolation region is needed. Hence, the p-type impurity elements (for example, boron) are diffused from the p⁺-type semiconductor region 20 to the side of the n-type epitaxial growth layer. The region where the p-type impurity elements are diffused is, in FIG. 2B, shown as a p-type region 20p. Accordingly, the effective thickness of the n-type epitaxial growth layer is reduced.

Thus, the extension of a depletion layer in the n-type epitaxial growth layer is decreased as compared with the first embodiment, and the capacitance of the p-n diode 40 is increased as compared with the first embodiment. The accumulation of the thermal treatment causes the impurity elements included in the element isolation regions 103 and 106 to thermally diffuse each time. Hence, the widths of the element isolation regions 103 and 106 inevitably have predetermined lengths.

Therefore, in the reference example, it is difficult to shorten a distance L between interconnects connecting the p-n diode 40 and the p-n diode 41, which causes limitation on the decrease in the interconnect capacity.

On the other hand, in the semiconductor device 1 according to the first embodiment, an element isolation region is not formed by impurity diffusion but the insulating layers 50 and 51 are used as the element isolation region. Hence, the accumulation of the thermal treatment is reduced as compared with the reference example, and thus it is difficult for the p-type impurity elements (for example, boron) to be diffused from the p⁺-type semiconductor region 20 to the side of the n-type epitaxial growth layer. Accordingly, the effective thickness of the n-type epitaxial growth layer remains substantially the same, and the extension of the depletion layer in the n-type epitaxial growth layer is increased as compared with the reference example. In other words, the capacitance of the p-n diode 40 is decreased as compared with the reference example.

The widths of the insulating layers 50 and 51 are shorter than the widths of the element isolation regions 103 and 106. Accordingly, it is possible to perform design such that the distance L between interconnects connecting the p-n diode 40 and the p-n diode 41 is short.

### Second Embodiment

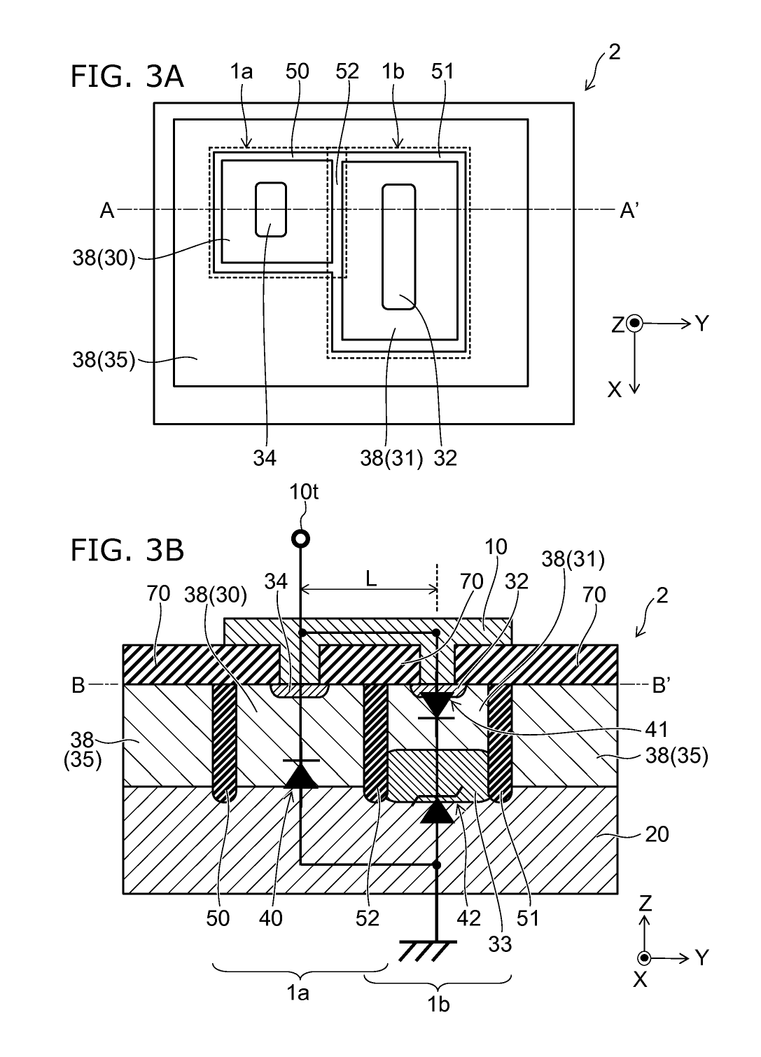

FIG. 3A is a schematic plan view showing a semiconductor device according to a second embodiment, and FIG. 3B is a schematic cross-sectional view taken along line A-A′ of the semiconductor device according to the second embodiment shown in FIG. 3A.

FIG. 3A shows the upper face of a cross section taken along line B-B′ of FIG. 3B.

In a semiconductor device 2 according to the second embodiment, at least part of the insulating layer 50 and at least part of the insulating layer 51 are shared. The shared region is denoted as a region 52. The region 52 belongs to both the insulating layer 50 and the insulating layer 51.

In the first embodiment, the third portion 35 of the semiconductor region 38 between the insulating layer 50 and the insulating layer 51 is an unused region. In the semiconductor device 2 according to the second embodiment, at least part of the insulating layer 50 and at least part of the insulating layer 51 are shared, the unused region is reduced and the distance L between interconnects is further shortened. Accordingly, in the semiconductor device 2, the interconnect capacity is further decreased as compared with the semiconductor device 1.

### Third Embodiment

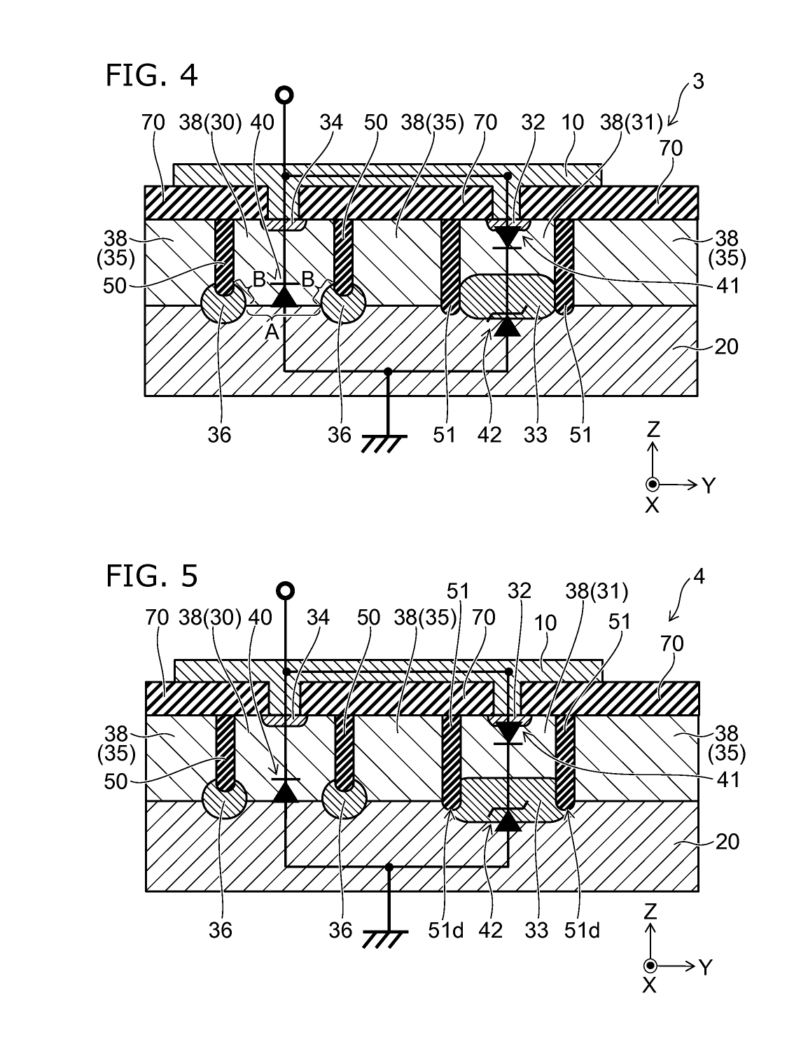

FIG. 4 is a schematic cross-sectional view showing part of a semiconductor device according to a third embodiment.

In the semiconductor device 3 according to the third embodiment, a p⁺-type fifth semiconductor region 36 (hereinafter, for example, a semiconductor region 36) is provided between the insulating layer 50 and the semiconductor region 20. The semiconductor region 36 is a region that is obtained by implanting p-type impurity elements between the insulating layer 50 and the semiconductor region 20, and then by thermally diffusing the impurity elements. In the semiconductor device 3, the insulating layer 50 and the semiconductor region 36 are the element isolation region of the p-n diode 40.

In the semiconductor device 3, the semiconductor region 36 is provided between the insulating layer 50 and the semiconductor region 20. Hence, the amount of impurity elements implanted to form the semiconductor region 36 is less than the amount of impurity elements implanted to form the semiconductor region 101.

Hence, even when the impurity diffusion region becomes part of the element isolation region, the accumulation of the thermal treatment is reduced as compared with the reference example. Accordingly, in the semiconductor device 3, it is difficult for the p-type impurity elements (for example, boron) to be diffused from the p⁺-type semiconductor region 20 to the side of the n-type epitaxial growth layer. In other words, in the semiconductor device 3, the same effect as in the semiconductor device 1 is also achieved.

In the semiconductor device 3, the p-n junction portion of the p-n diode 40 includes the junction portion (A part in the figure) of the p⁺-type semiconductor region 20 and the first portion 30 of the n-type semiconductor region 38 and the junction portion (B part in the figure) of the p⁺-type semiconductor region 36 and the first portion 30 of the semiconductor region 38. Hence, in the semiconductor device 3, the p-n junction area of the p-n diode 40 is increased as compared with the semiconductor device 1. Accordingly, the current capacity of the p-n diode 40 is increased.

An ESD tolerance amount is determined by the tolerance of a diode whose current capacity is relatively low among the p-n diode 40, the p-n diode 41 and the Zener diode 42. Among the p-n diode 40, the p-n diode 41 and the Zener diode 42, the tolerance of the p-n diode 40 whose current capacity is relatively low is increased, and thus the ESD tolerance amount of the semiconductor device 3 is further increased.

### Fourth Embodiment

FIG. 5 is a schematic cross-sectional view showing part of a semiconductor device according to a fourth embodiment.

In the semiconductor device 4 according to the fourth embodiment, the n⁺-type semiconductor region 33 is in contact with the lower end 51d of the insulating layer 51. In other words, the junction area of the p⁺-type semiconductor region 20 and the n⁺-type semiconductor region 33 is further increased.

Accordingly, the p-n junction area of the Zener diode 42 is further increased. In the semiconductor device 4, the breakdown tolerance amount when a revere bias is applied to the Zener diode 42 is further increased.

### Fifth Embodiment

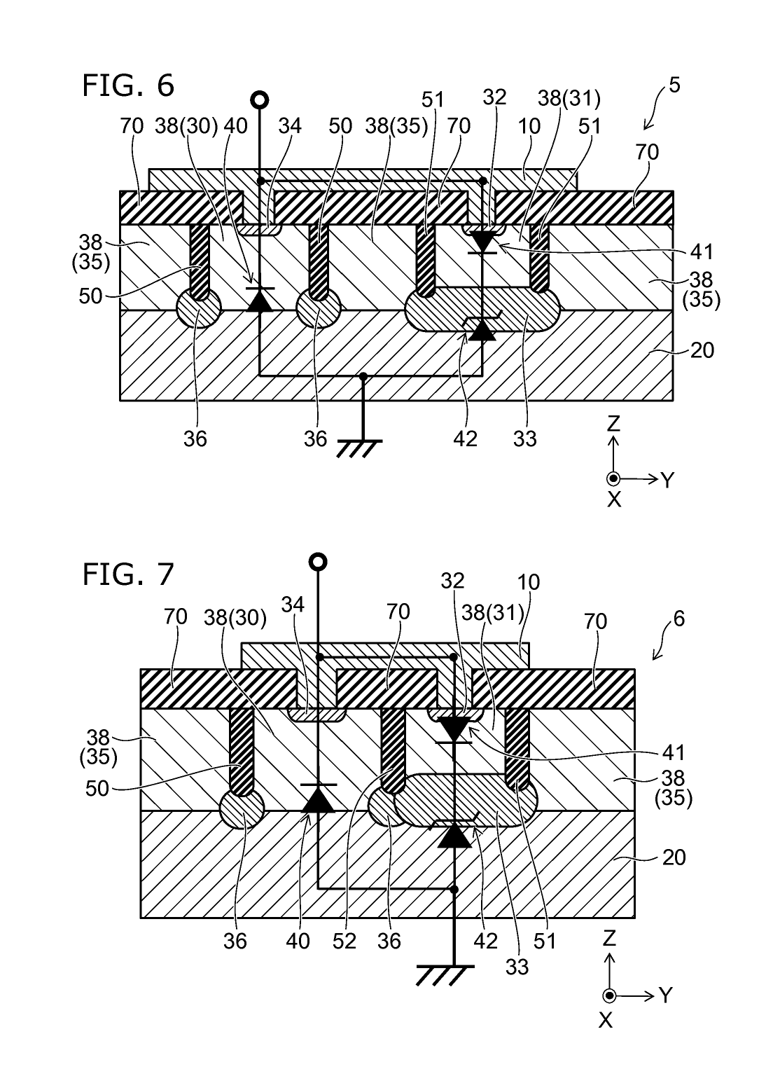

FIG. 6 is a schematic cross-sectional view showing part of a semiconductor device according to a fifth embodiment.

In the semiconductor device 5 according to the fifth embodiment, the n⁺-type semiconductor region 33 is provided between the second portion 31 of the semiconductor region 38 and the semiconductor region 20 and between the insulating layer 51 and the semiconductor region 20.

The semiconductor region 33 is a region that is obtained by implanting n-type impurity elements between the insulating layer 51 and the semiconductor region 20, and then by thermally diffusing the impurity elements. In the semiconductor device 5, the semiconductor region 20 and the semiconductor region 33 form the Zener diode 42, and the insulating layer 51 and the semiconductor region 33 are the element isolation region of the p-n diode 41 and the Zener diode 42.

In the structure described above, the p-n junction area of the Zener diode 42 is further increased. In other words, in the semiconductor device 5, the breakdown tolerance amount when a revere bias is applied to the Zener diode 42 is further increased.

### Sixth Embodiment

FIG. 7 is a schematic cross-sectional view showing part of a semiconductor device according to a sixth embodiment.

In the semiconductor device 6 according to the sixth embodiment, at least part of the insulating layer 50 and at least part of the insulating layer 51 are shared. The shared region is denoted as the region 52.

In the semiconductor device 6, the p⁺-type semiconductor region 36 is provided between the insulating layer 50 and the semiconductor region 20. In the semiconductor device 6, the n⁺-type semiconductor region 33 is provided between the second portion 31 of the semiconductor region 38 and the semiconductor region 20, between the insulating layer 51 and the semiconductor region 20 and between the region 52 and the semiconductor region 20. The semiconductor device 6 described above is also included in the embodiment.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region of first conductivity-type;
a second semiconductor region of second conductivity-type provided on the first semiconductor region, and second semiconductor region being connected to the first semiconductor region;
a first insulating layer surrounding a first portion of the second semiconductor region;
a second insulating layer surrounding a second portion of the second semiconductor region;
a third semiconductor region of first conductivity-type provided on the second portion of the second semiconductor region, the third semiconductor region being connected to the second portion, and the third semiconductor region being surrounded by the second insulating layer; and
an interconnect layer provided on the second semiconductor region and the third semiconductor region, and the interconnect layer being electrically connected to the second semiconductor region and the third semiconductor region.

2. The device according to claim 1, wherein
the interconnect layer is electrically connected to the first portion of the second semiconductor region.

3. The device according to claim 1, further comprising:
a fourth semiconductor region of second conductivity-type between the first semiconductor region and the second portion of the second semiconductor region.

4. The device according to claim 3, further comprising:
an interlayer insulating film between the second semiconductor region and the interconnect layer,
an upper end of the second insulating layer being in contact with the interlayer insulating film and a lower end of the second insulating layer being in contact with the fourth semiconductor region.

5. The device according to claim 3, wherein
an impurity concentration in the fourth semiconductor region is higher than an impurity concentration in the second semiconductor region.

6. The device according to claim 5, wherein
the fourth semiconductor region is surrounded by the second insulating layer.

7. The device according to claim 1, further comprising:
an interlayer insulating film between the second semiconductor region and the interconnect layer, an upper end of the first insulating layer being in contact with the interlayer insulating film and a lower end of the first insulating layer being in contact with the first semiconductor region.

8. The device according to claim 1, further comprising:
an interlayer insulating film between the second semiconductor region and the interconnect layer,
an upper end of the second insulating layer being in contact with the interlayer insulating film and a lower end of the second insulating layer being in contact with the first semiconductor region.

9. The device according to claim 1, wherein
a part of the first insulating layer and a part of the second insulating layer are shared.

10. The device according to claim 1, further comprising:
a fifth semiconductor region of first conductivity-type between the first insulating layer and the first semiconductor region.

11. The device according to claim 10, further comprising:
an interlayer insulating film between the second semiconductor region and the interconnect layer,
an upper end of the first insulating layer being in contact with the interlayer insulating film and a lower end of the first insulating layer being in contact with the fifth semiconductor region.

12. The device according to claim 10, wherein
the first portion of the second semiconductor region is surrounded by the first insulating layer and the fifth semiconductor region.

13. The device according to claim 1, further comprising:
a forth semiconductor region of second conductivity-type between the first semiconductor region and the second portion of the second semiconductor region.

14. The device according to claim 13, wherein
the fifth semiconductor region is in contact with the fourth semiconductor region.

15. The device according to claim 10, wherein
a part of the first insulating layer and a part of the second insulating layer are shared.

16. The device according to claim 15, further comprising:
a fourth semiconductor region of second conductivity-type between the first semiconductor region and the second portion of the second semiconductor region,
a lower end of a layer being in contact with the fourth semiconductor region and the fifth semiconductor region, and the first insulating layer and the second insulating layer are shared in the layer.

17. The device according to claim 1, further comprising:
a sixth semiconductor region of second conductivity-type between the first portion of the second semiconductor region and the interconnect layer.

18. The device according to claim 15, wherein
an impurity concentration of the sixth semiconductor region is higher than an impurity concentration of the second semiconductor region.

19. The device according to claim 1, wherein
the first portion is completely surrounded by the first insulating layer.

20. The device according to claim 1, wherein
the second portion is completely surrounded by the second insulating layer.
